(19) United States
(12) Patent Application Publication
(10) Pub. No.: US 2021/0269348 A1
(43) Pub. Date: Sep. 2, 2021

(54) HOT GLASS 3D PRINTING HEAD AND METHOD

(71) Applicant: CORNING INCORPORATED, Corning, NY (US)

(72) Inventors: Christopher William Drewnowski, Corning, NY (US); Paul Oakley Johnson, Corning, NY (US); Charles Thomas McLaren, Elmira, NY (US); Kristen Dae Waight, Lindley, NY (US)

(21) Appl. No.: 17/186,420

(22) Filed: Feb. 26, 2021

Related U.S. Application Data
(60) Provisional application No. 62/983,656, filed on Feb. 29, 2020.

(51) Int. Cl. C03B 19/02; C30B 35/00; B33Y 10/00; B33Y 30/00; B33Y 40/00

(52) U.S. Cl. CPC C03B 19/025; C30B 35/002; B29C 64/118; B33Y 30/00; B33Y 40/00; B33Y 10/00

(57) ABSTRACT

An apparatus for dispensing hot glass during 3D printing includes a crucible with a cylindrical barrel open at a proximal end and an aperture at a distal end, a holder-actuator to hold a glass rod feedstock and move the feedstock into and within the barrel, a first heater on or adjacent the outer surface of the barrel, and a second heater on or adjacent the outer surface of the barrel energized independently, and positioned proximally, of the first heater. A method of dispensing glass during 3D printing includes feeding a glass rod feedstock into the proximal, open end of a crucible having an aperture at its distal end while maintaining the crucible at a first position within a first temperature range and maintaining the crucible at second position, proximal of the first position, within a second temperature range lower than the first temperature range.

This application claims the benefit of priority under 35 U.S.C. § 119 of U.S. Provisional Application Ser. No. 62/983,656, filed on Feb. 29, 2020, the content of which is incorporated herein by reference in its entirety.

### BACKGROUND

This disclosure relates a printing head for 3D printing of glass in a heated state and to methods of 3D printing enabled by the printing head and/or using the printing head.

In WO2018002001A1, a fused quartz glass 3D printing method uses a cooled nozzle from which a solid glass wire or rod is fed, and the wire or rod is melted below the nozzle, after the wire or rod exits the nozzle, rather than extruded from the nozzle in melted form. In WO2018163006A1, glass filament feed material is fed through a printing nozzle which nozzle includes both an upstream cooling unit and a heater near the tip of the nozzle. In US20180147826A1, glass is melted in a crucible positioned within a crucible kiln from which it flows downward through a nozzle positioned within a nozzle kiln. WO2017189904A1 discloses a 3D printer with separate temperature controls for a heated nozzle and a heated build plate.

In WO2018098435A1 a glass rod, rather than a filament, is used as a glass feedstock to fed under force by an actuator into a crucible having an aperture at the distal end thereof for 3D printing of molten glass and a heater positioned near the end thereof for heating the feedstock. Use of the rod as feedstock instead of traditional filaments has some advantages. Use of a rod as feedstock can allow longer operating times between when the system must be reloaded with more feedstock. The rod can also act as a piston to provide a direct force modulated or position control over the extrusion pressure and extrusion rate of melted glass at the aperture. Also, quick removal of the force applied by the actuator to the rod—or a slight pull back on the feedstock rod—at the end of a print segment can cause the feedstock material to pull back into the aperture, which can help with the process of starting and stopping the material flow and reducing or eliminating “hairs” or fine strands of material extending away from the a printed article or segment at a segment's end point.

### SUMMARY

In 3D print systems of this type last type, the present inventors have discovered that is it is possible for a thermal conditions within the crucible to be such that low viscosity molten glass can back flow along the feed rod reducing the piston like effect of the rod. The back flow may even in some cases reach a point sufficiently far from the crucible aperture to cool and solidify, causing the feedstock to jam or adhere tightly within the crucible. The present inventors have found that good performance is obtained during 3D printing of a glass rod feedstock in a printing system of this last type by maintaining the distal end of the crucible within a first temperature range, while maintaining a second portion of the crucible, spaced proximally from the distal end, within a second temperature range lower than the first, with the second temperature range selected to correspond to a feedstock viscosity of between 10⁸-10¹¹ poise, desirably between 10⁹-10¹⁰ poise.

Without wishing to be bound by theory, it is possible that, by maintaining these temperature ranges at these locations, any backflowing molten glass is kept in a viscoelastic state so as not to cool and solidify sufficiently to cause the feedstock to jam or adhere tightly within the crucible. Alternatively, it is possible that, by maintaining these temperature ranges at these locations, sufficient slight deformation of the feedstock rod is achieved at the sufficient to effectively seal cross section of the crucible and prevent the molten glass at the distal end of the crucible from flowing back along the crucible, while simultaneously keeping a sufficiently high viscosity of the feedstock at the second portion of the crucible to maintain the advantages of piston like effects of the rod.

Accordingly, disclosed herein is a method of dispensing glass during 3D printing, the method comprising feeding a glass rod feedstock into the proximal and open end of a cylindrical barrel of a crucible, the crucible having an aperture at a distal end of the crucible, the aperture in fluid communication with the barrel and having an aperture cross section, the barrel cross section being larger than the aperture cross section; maintaining the crucible at a first position within a first temperature range; and maintaining the crucible at second position proximal of the first position within a second temperature range lower than the first temperature range. The second temperature range is desirably selected to correspond to a feedstock viscosity of between 10⁸-10 poise, more desirably between 10⁹-10¹⁰ poise.

Also disclosed herein is an apparatus for dispensing hot glass during 3D printing, the apparatus comprising (1) a crucible, the crucible comprising (a) a cylindrical barrel open at a proximal end of the crucible and having a barrel axis and a barrel cross section and an inner barrel surface and outer barrel surface and (b) an aperture at a distal end of the crucible in fluid communication with the barrel and having an aperture cross section, the barrel cross section being larger than the aperture cross section; (2) a holder-actuator positioned proximally of the barrel and structured to hold a glass rod feedstock, when present, and to move the feedstock within the barrel along a direction generally parallel to the axis of the barrel; (3) a first heater positioned on or adjacent to the outer surface of the barrel; and (4) a second heater energized independently of the first heater and positioned on or adjacent to the outer surface of the barrel proximally of the first heater. The second heater can mounted in an adjustable mount such that a distance between the first and second heaters is adjustable. The adjustable mount can manually repositionable or automatically repositionable.

The apparatus can further comprise a third heater positioned on or adjacent to the outer surface of the barrel proximally of the second heater and energized independently of the first heater and the second heater. The third heater can be mounted in a second adjustable mount such that a distance between the second and third heaters is also adjustable. The second adjustable mount can also be manually repositionable or automatically repositionable.

This apparatus can provide the advantages of rod-form glass feed stock, such as improved control of extrusion/flow of molten glass during 3D printing, and/or improved control over starting and stopping extrusion/flow, without the problem of feedstock jamming within the crucible.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a combined diagrammatic and cross sectional representation of an apparatus according to an embodiment of apparatuses the present disclosure;

FIG. 2 is a combined diagrammatic and cross sectional representation of an apparatus according to certain alternative embodiments of apparatuses the present disclosure; and

FIG. 3 is a cross sectional view of a (prior art) crucible usable with the methods and apparatuses of the present disclosure.

### DETAILED DESCRIPTION

Reference will now be made in detail to various embodiments.

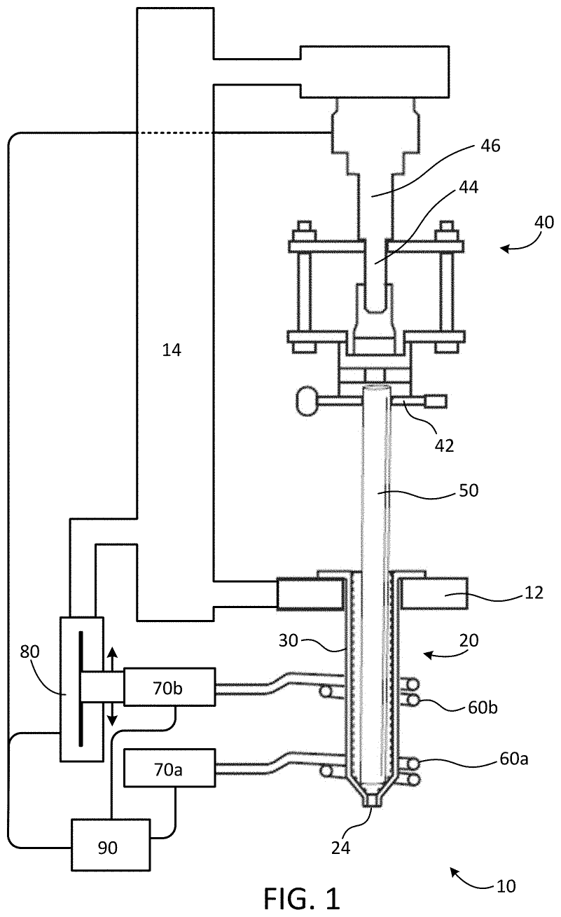

As shown in FIG. 1, an embodiment of apparatus 10 for dispensing hot glass during 3D printing, according to the present disclosure includes a crucible 20, supported in this embodiment in and opening in a retainer 12, with the retainer 12 mounted on a support frame 14.

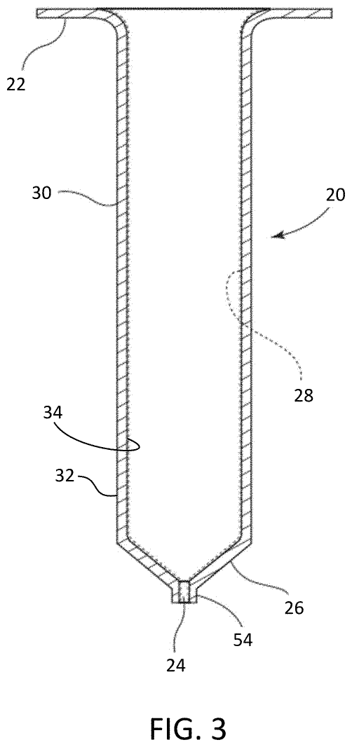

The crucible 20 comprises a cylindrical barrel 30 open at a proximal end of the crucible 20 and having a barrel axis and a barrel cross section and an inner barrel surface 32 and outer barrel surface 34 (shown in FIG. 3), and an aperture 24 at a distal end of the crucible in fluid communication with the barrel. The aperture 24 as an aperture cross section, with the barrel cross section being larger than the aperture cross section.

The apparatus 10 further comprises a holder-actuator 40 positioned proximally of the barrel 30 and structured to hold a glass rod feedstock 50, when present, and to move the feedstock 50 within the barrel 30 along a direction generally parallel to the axis of the barrel 30. In the embodiment shown in FIG. 1, the holder-actuator 40 comprises a gripping mechanism 42 mounted on a piston 44 in a piston actuator 46. The holder-actuator 40 can be supported on the support frame 14.

The apparatus 10 further comprises a first heater 60a positioned on or adjacent to the outer surface 32 of the barrel 30 and a second heater 60b positioned on or adjacent to the outer surface 32 of the barrel 30, proximally of the first heater 60a. The second heater 60b is energized independently of the first heater 60a, such as by respective heater drivers 70a and 70b as shown in FIG. 1. Heaters 60a and 60b are represented as inductive heaters but can take other forms, such as resistive heaters, thermoelectric heaters, and others. A an electronic controller 90 of some form, such as a programmable electronic controller, can be used to control the heater drives 70a and 70b (and thereby the heaters 760a and 60b). Feedback of sensed temperatures at the crucible 20 can also be used to for the controller 90.

The apparatus 10 can have the second heater 60b mounted on an adjustable mount 80 such that a distance between the first and second heaters 60a, 60b is adjustable. The adjustable mount 80 can be manually repositionable and/or automatically repositionable, optionally under control of the controller 90. The holder-actuator 40, or as in the embodiment of FIG. 1, the piston actuator 46, can also operate under control of the controller 90.

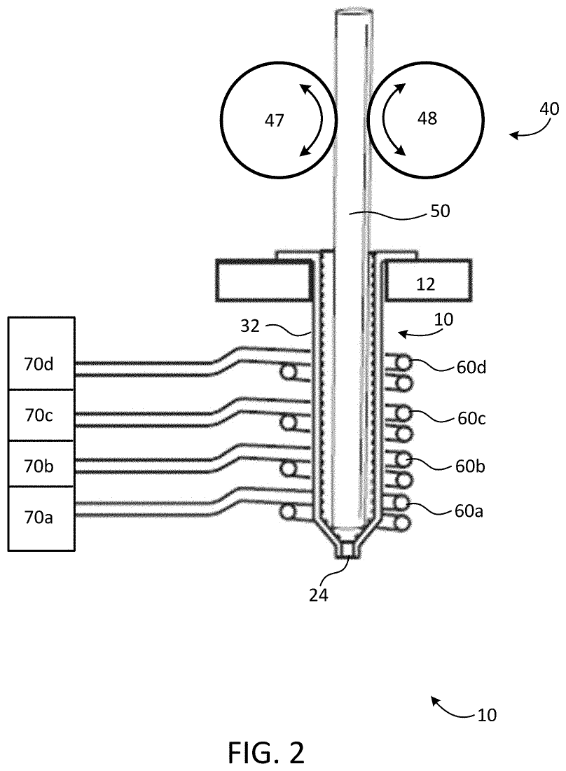

In other embodiments according to the present disclosure illustrated in FIG. 2, the apparatus 10 can further comprise a third heater 60c positioned on or adjacent to the outer surface 32 of the barrel 30, proximally of the second heater 60b, and energized independently of the first heater 60a and the second heater 60b, such as by third heater drive 70c as shown. A fourth heater 60d with a fourth heater driver 70d can optionally be added also, and potentially more if needed. These additional heaters can also be mounted in adjustable mounts, to be manually and/or automatically repositionable. As further shown in FIG. 2, in other embodiments according to the present disclosure, the holder-actuator 40 may take the form of cooperating wheels 47, 48, with one or both of the cooperating wheels being rotatably actuated to move the feedstock 50 as desired.

Further according to other embodiments of the present disclosure, a method of dispensing glass during 3D printing is provided, the method comprising: (1) feeding a glass rod feedstock 50 into the proximal and open end of a cylindrical barrel 30 of a crucible 20, the crucible having an aperture 24 at a distal end of the crucible 20, the aperture 24 being in fluid communication with the interior of the barrel 30—the aperture 24 also has an aperture cross section with the barrel cross section being larger than the aperture cross section; (2) maintaining the crucible 20 at a first position (corresponding to the location of the first heater 60a) within a first temperature range; and (3) maintaining the crucible 20 at second position proximal of the first position (the second position corresponding to the location of the second heater 60b) within a second temperature range lower than the first temperature range. In this method, the second temperature range is desirably selected to correspond to a feedstock viscosity of between 10⁸-10¹¹ poise, more desirably of between 10⁹-10¹⁰ poise.

FIG. 3 shows some additional preferred features of the crucible 20 from the prior art, including a flared rim 22 at the proximal end of the crucible 20 for assisting in supporting the crucible 20 in the retainer 12 of FIGS. 1 and 2, and a narrowing portion or “knuckle” 26 which narrows gradually from the barrel 30 to the aperture 24. The inner surface 34 of the barrel 30 (and of the crucible 20 as a whole) may include a coating 28.

It will be apparent to those skilled in the art that various modifications and variations can be made without departing from the spirit or scope of the disclosure. For example, the directions shown within the figures herein are not to be taken as limiting and the embodiments of the apparatuses disclosed may be operated in various orientations. “Proximal” and “distal” are in this sense relative indications of position within the immediately described structure only, and have no connection to any larger frame of reference.

What is claimed is:

1. An apparatus for dispensing hot glass during 3D printing, the apparatus comprising:
a crucible comprising
a cylindrical barrel open at a proximal end of the crucible and having a barrel axis and a barrel cross section and an inner barrel surface and outer barrel surface, and
an aperture at a distal end of the crucible in fluid communication with the barrel and having an aperture cross section, the barrel cross section being larger than the aperture cross section;
a holder-actuator positioned proximally of the barrel and structured to hold a glass rod feedstock, when present, and to move the feedstock within the barrel along a direction generally parallel to the axis of the barrel;
a first heater positioned on or adjacent to the outer surface of the barrel; and
a second heater energized independently of the first heater and positioned on or adjacent to the outer surface of the barrel proximally of the first heater.

2. The apparatus of claim 1, wherein the second heater is mounted in an adjustable mount such that a distance between the first and second heaters is adjustable.

3. The apparatus of claim 2, wherein the adjustable mount is manually repositionable.

4. The apparatus of claim 2, wherein the adjustable mount is automatically repositionable.

5. The apparatus of claim 1, further comprising a third heater positioned on or adjacent to the outer surface of the barrel proximally of the second heater and energized independently of the first heater and the second heater.

6. The apparatus of claim 5, wherein the third heater is mounted in a second adjustable mount such that a distance between the second and third heaters is adjustable.

7. The apparatus of claim 6, wherein the second adjustable mount is manually repositionable.

8. The apparatus of claim 6, wherein the second adjustable mount is automatically repositionable.

9. A method of dispensing glass during 3D printing the method comprising:
feeding a glass rod feedstock into the proximal and open end of a cylindrical barrel of a crucible, the crucible having an aperture at a distal end of the crucible, the aperture in fluid communication with the barrel and having an aperture cross section, the barrel cross section being larger than the aperture cross section;
maintaining the crucible at a first position within a first temperature range; and
maintaining the crucible at second position proximal of the first position within a second temperature range lower than the first temperature range.

10. The method according to claim 9, wherein the second temperature range is selected to correspond to a feedstock viscosity of between 10⁸-10¹¹ poise.
